(19) United States
(12) Patent Application Publication
(10) Pub. No.: US 2004/0080356 A1
(43) Pub. Date: Apr. 29, 2004

(54) Compact input/output signal driver for electrostatic discharge protection

(76) Inventors: Scott A. Hareland, Tigard, OR (US); Sunit Tyagi, Portland, OR (US)

Correspondence Address: Timothy N. Trop, TROP, PRUNER & HU, P.C., STE 100, 8554 KATY FWY, HOUSTON, TX, 77024-1841, US

(21) Appl. No.: 10/280,926

(22) Filed: Oct. 25, 2002

(51) Int. Cl. H01L 29/76

(52) U.S. Cl. 327/401; 257/401

(57) ABSTRACT

A pair of C-shaped gate electrodes may define a pair of transistors and a pair of diodes for forming an input/output signal driver for electrostatic discharge protection. Because of the compact arrangement, silicon real estate may be conserved in silicon-on-insulator substrates.

### BACKGROUND

This invention relates generally to integrated circuits.

Input signals to an integrated circuit, such as a metal oxide semiconductor (MOS) integrated circuit, are generally fed to transistors. If the applied voltage becomes excessive, the gate oxide of a transistor can break down, its junctions may be destroyed, and the connection to the transistor may also be destroyed.

Excessive voltages are voltages in excess of the normal operating voltages of the circuit. One common source of high voltages applied to integrated circuits is triboelectricity. Triboelectricity is the result of rubbing two materials together. A person may develop relatively high static voltage simply by walking across a room or by removing an integrated circuit from its plastic package.

As such a high voltage is applied to an input pin of an integrated circuit package, its discharge, referred to as electrostatic discharge (ESD), can cause breakdown of the devices to which the voltage is applied. This breakdown may cause sufficient damage to result in immediate destruction of the integrated circuit or it may sufficiently weaken the device that it will fail early in its operating life.

In general, input pins of integrated circuits are provided with protection circuits to prevent excessive voltages from damaging MOS transistors. These protection circuits are normally placed at the input and output pads on an integrated circuit and the transistor gates to which the pads are coupled. These protection circuits begin conducting or undergo breakdown, thereby providing an electrical path to ground or to the power supply rail, in the presence of excessive voltages that would result in electrostatic discharge. Since the breakdown mechanism is designed to be nondestructive, the circuit generally provides an open path that closes only when high voltage appears at the input or output terminals, harmlessly discharging the node to which it is connected.

Traditional bulk complementary metal oxide semiconductor (CMOS) input/output circuits utilize the natural diodes formed on the NMOS and PMOS output driver transistors for ESD protection. These natural diodes are formed between the p+ drain and n-well of PMOS devices and the n+ drain and p-well of NMOS devices.

In silicon-on-insulator (SOI) technologies, these natural diodes between diffusions and wells of the substrate do not exist. Typically, isolated lateral diodes are used to provide diode based electrostatic discharge protection to input/output circuits. Isolated lateral diodes may suffer from layout inefficiencies due to the requirement for additional silicon area used for forming the diodes.

Thus, there is a need for better ways to provide input/output driver circuits for electrostatic discharge protection for silicon-on-insulator technologies.

### BRIEF DESCRIPTION OF THE DRAWINGS

FIG. 1 is a circuit diagram in accordance with one embodiment of the present invention;

FIG. 2 is an enlarged layout diagram for implementing a portion of the circuit shown in FIG. 1;

FIG. 3 is a top plan view of the layout shown in FIG. 2 at an early stage of its fabrication;

FIG. 4 is a top plan view of the embodiment shown in FIG. 3 at a subsequent stage of fabrication;

FIG. 5 is a top plan view of the embodiment shown in FIG. 4 at a subsequent state of fabrication;

FIG. 6 is an enlarged cross-sectional view taken generally along the line 6-6 in FIG. 5;

FIG. 7 is an enlarged cross-sectional view taken generally along the line 7-7 in FIG. 5; and

FIG. 8 is an enlarged cross-sectional view taken generally along the line 8-8 in FIG. 5.

### DETAILED DESCRIPTION

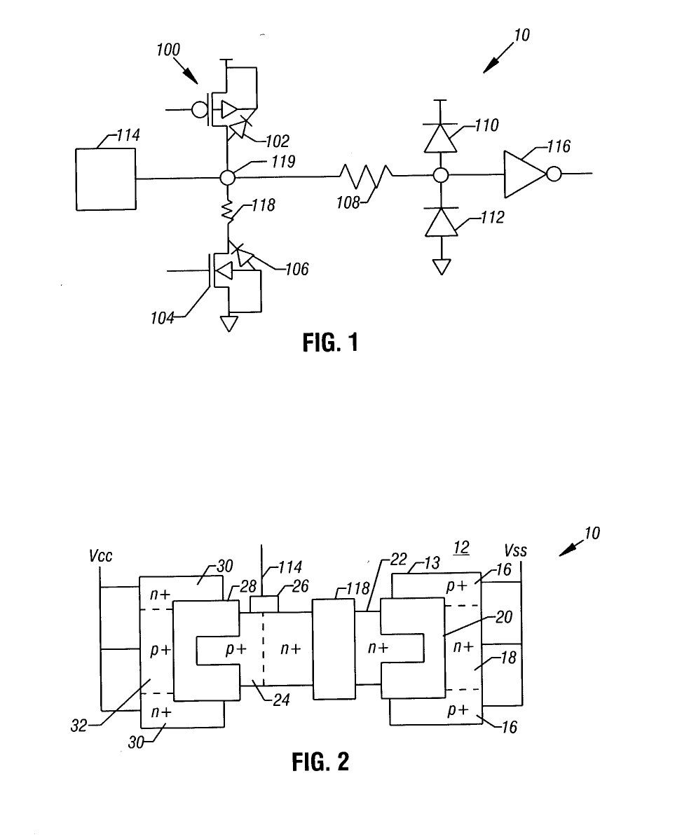

Referring to FIG. 1, an input/output signal driver circuit 10 may include a pad contact 114 coupled at node 119 between a pair of metal oxide semiconductor transistors 100 and 104. The PMOS pull up transistor 100 is coupled to a supply voltage V_{cc} while the NMOS pull down transistor 104 is coupled to the source of the transistor 100 and to Vₛₛ in one embodiment. Between the node 119 and the transistor 104 is a ballast resistor 118. Also coupled across each transistor 100, 104 is a rectifying lateral diode 102 or 106.

The input/output signal driver circuit 10 also includes a resistor 108, a pair of diodes 110 and 112, and an amplifier 116. These components may be implemented conventionally in one embodiment of the present invention.

Referring to FIG. 2, in accordance with one embodiment of the present invention, an integrated circuit implementation of a portion of the circuit shown in FIG. 1 may be arranged in a relatively compact arrangement. In particular, the transistor 100 may be implemented by a drain diffusion 32 (which may be a p+ region in one embodiment coupled to V_{cc}) a gate electrode 28, and a source 24 (which may also be a p+ region in one embodiment). The source 24 may be coupled to the contact pad 114 through a contact 26.

Similarly, the transistor 104 may be realized by the source 18 (which may be an n+ region in one embodiment coupled to Vₛₛ), the gate electrode 20, and the drain 22 (which may be an n+ region, in one embodiment of the present invention). The drain 22 may be coupled to the ballast resistor 118 which, in turn, is coupled to the transistor 100 through the source 24. A diode may not be formed between the p+ source 24 and the adjacent n+ region since these regions are shorted by subsequent overlying layers. The surrounding substrate may be a silicon-on-insulator substrate in accordance with one embodiment of the present invention.

The diode 102, shown in FIG. 1, may be formed by the source 24, the gate 28, and the n+ region 30. Similarly, the diode 106 may be formed from the p+ region 16, the gate 20, and the drain 22. Thus, it may be appreciated that the C-shaped gate electrode 28 functions not only to define the transistor 100 but also to define the diode 102. Similarly, the gate electrode 20 defines not only the transistor 104 but also the diode 106. As a result, in some embodiments, a very compact, very efficient layout is achieved.

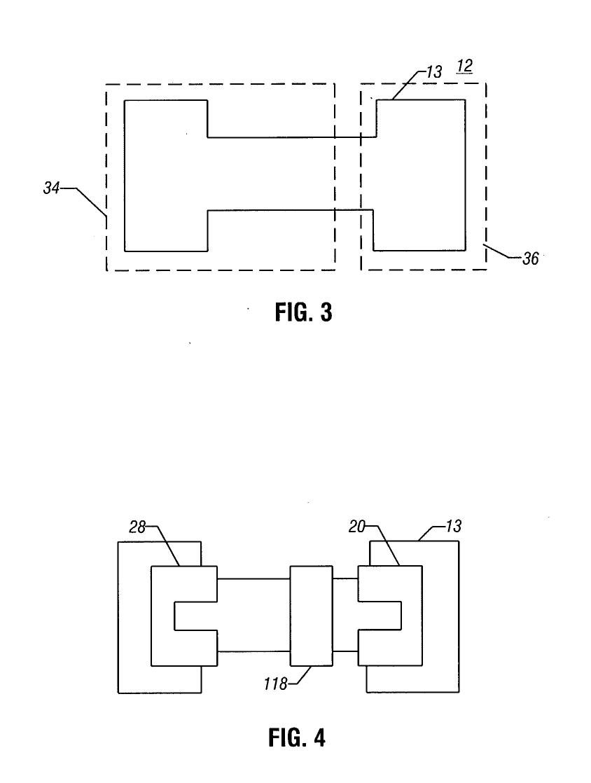

Turning next to FIG. 3, initially, in one embodiment, a p-well 36 and an n-well 34 may be formed in a silicon-on-insulator substrate 12. An active region 13 may be defined. Outside the active region 13 may be isolation material in one embodiment.

Referring to FIG. 4, in accordance with one embodiment, polysilicon or other gate material 28, 118, and 20 may be deposited and patterned to form the C-shaped gate electrodes 28 and 20 and the ballast resistor 118.

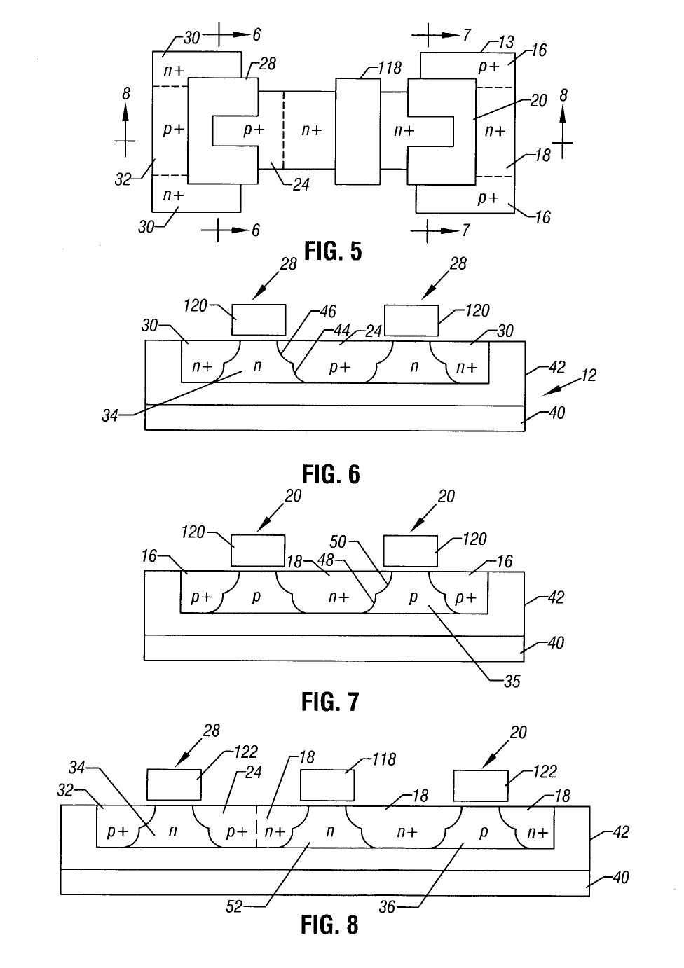

Turning next to FIG. 5, ion implantation or other source/drain or junction formation techniques may be utilized to p+ regions 16, n+ region 18, and the p+ region 24, as well as the n+ region 30. The silicon-on-insulator substrate 12 may include the inactive silicon material 40 positioned under an insulator 42 in one embodiment of the present invention.

Thus, referring to FIG. 6, the diode 102 may be formed by the n+ region 30, the n-type region 34, and the p+ region 24. In one embodiment, the graded junction region 46 may be the result of a tip or extension implant of a source/drain implant and the graded junction region 44 may be formed by a deeper source/drain implant.

Referring to FIG. 7, similarly, the diode 106 may be formed of the p+ region 16, the p-type region 35 under the gate 20, and the n+ region 18 having a graded junction at 48 and 50.

Finally, referring to FIG. 8, the transistor 100 has a gate electrode 28, p+ regions 32 and 24, and the channel 34. The ballast resistor 118 may be made up of the n+ region 18, the n-type region 52, and the n+ region 18. The transistor 104 may be formed from the n+ region 18, the p-type region 36, and the n+region 18 all under the gate electrode 20.

Thus, through the use of the C-shaped gate electrodes 28 and 20, a pair of transistors and a pair of diodes may be separately formed in substantially the same active area. Each transistor 100 or 104 has a gate length defined by the connecting segment 122. Each lateral diode 102 or 106 is defined by the parallel of gate segments 120.

A basic structure can be replicated on a large scale to achieve the necessary PMOS and/or NMOS transistor width. The size of lateral diodes 102 and 106 may be adjusted by varying the number of segments and the gate segment 120 length that defines the diodes. For example, the width of the segments 120 that define the diode can be adjusted to allow for registration tolerance when aligning n+ and p+ implants in the various regions. An integrated layout may provide more efficient use of silicon real estate for silicon-on-insulator substrates compared to isolated transistor and diode structures.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An input/output signal driver comprising:
a first C-shaped gate electrode;
a first diode including said first C-shaped gate electrode; and
a first transistor including said first C-shaped gate electrode.

2. The driver of claim 1 including a silicon-on-insulator substrate, said first C-shaped gate electrode formed over said substrate.

3. The driver of claim 2 including a second C-shaped gate electrode, a second diode, and a second transistor, said second C-shaped gate electrode forming part of said second diode and said second transistor.

4. The driver of claim 3 including a ballast resistor formed between said C-shaped gate electrodes.

5. The driver of claim 2 wherein said gate electrode includes two substantially parallel extensions coupled by a connecting portion, said parallel extensions defining said diode and said connecting portion defining said transistor.

6. The driver of claim 5 wherein the substrate between said extensions is a first conductivity type and said substrate on the opposite side of said extensions is a second conductivity type.

7. A method comprising:
forming an electrode over a substrate;
defining a lateral diode using said electrode;
defining a transistor using said electrode; and
fabricating an input/output signal driver with electrostatic discharge protection using said diode and transistor.

8. The method of claim 7 including forming a second electrode over said substrate and defining a second lateral diode and a second transistor using said second electrode.

9. The method of claim 7 including defining said electrode in a C-shape.

10. The method of claim 7 including forming a pair of C-shaped electrodes over said substrate.

11. The method of claim 10 including defining a lateral diode and a transistor associated with each of said C-shaped electrodes and using said diodes, transistors, and electrodes to form an input/output signal driver with electrostatic discharge protection.

12. The method of claim 11 including forming a ballast resistor between said C-shaped electrodes.

13. An input/output signal driver comprising:
a first and second C-shaped gate electrode;
a first diode and a first transistor using said first C-shaped gate electrode; and
a second diode and a second transistor using said second C-shaped gate electrode.

14. The driver of claim 13 including a silicon-on-insulator substrate, said first C-shaped gate electrode formed over said substrate.

15. The driver of claim 14 including a ballast resistor formed between said first and second C-shaped gate electrodes.
